(19) United States
(12) Patent Application Publication
(10) Pub. No.: US 2017/0236807 A1
(43) Pub. Date: Aug. 17, 2017

(54) III-V MICRO-LED ARRAYS AND METHODS FOR PREPARING THE SAME

(71) Applicant: The Regents of the University of California, Oakland, CA (US)

(72) Inventors: David Hwang, Goleta, CA (US); Nathan G. Young, Goleta, CA (US); Ben Yonkee, Goleta, CA (US); Burhan K. Saifaddin, Goleta, CA (US); Steven P. DenBaars, Goleta, CA (US); James S. Speck, Santa Barbara, CA (US); Shuji Nakamura, Santa Barbara, CA (US)

(73) Assignee: The Regents of the University of California, Oakland, CA (US)

(21) Appl. No.: 15/582,215

(22) Filed: Apr. 28, 2017

Related U.S. Application Data
(63) Continuation-in-part of application No. PCT/US15/57850, filed on Oct. 28, 2015.
(60) Provisional application No. 62/069,644, filed on Oct. 28, 2014.
(60) Provisional application No. 62/329,696, filed on Apr. 29, 2016.

(51) Int. Cl. H01L 25/075; H01L 33/06; H01L 33/00; H01L 33/62; H01L 33/32; H01L 33/48

(52) U.S. Cl. CPC H01L 25/0756; H01L 33/32; H01L 33/486; H01L 33/0079; H01L 33/0075; H01L 33/62; H01L 33/06; H01L 2933/0033; H01L 2933/0066

(57) ABSTRACT

III-V micro light-emitting diodes (LEDs) are fabricated using a photoelectrochemical (PEC) etch. A sacrificial layer and III-V device layers are epitaxially grown on a host substrate, wherein the III-V device layers are patterned to form the micro-LEDs. The sacrificial layer is removed by a photoelectrochemical (PEC) etch, so as to fully or partially separate the micro-LEDs from the substrate, before or after the micro-LEDs are bonded to a submount or intermediate substrate. The micro-LEDs may be bonded to a submount with a polymer film deposited thereon, wherein the polymer film with the micro-LEDs is subsequently delaminated from the submount. Alternatively, the intermediate substrate may be a transfer medium, wherein the micro-LEDs are separated from the host substrate by mechanical fracturing, and then bonded to a second substrate, after which the intermediate substrate is removed, wherein a third substrate may be bonded to exposed surfaces of the transferred micro-LEDs.

### CROSS REFERENCE TO RELATED APPLICATIONS

This application is a continuation-in-part under 35 U.S.C. §120 and §365(c) of co-pending and commonly-assigned P.C.T. International Application Serial No. PCT/US15/57850, filed on Oct. 28, 2015, by David Hwang, Nathan G. Young, Ben Yonkee, Burhan K. Saifaddin, Steven P. DenBaars, James S. Speck and Shuji Nakamura, entitled “FLEXIBLE ARRAYS OF MICRO LIGHT EMITTING DIODES USING A PHOTOELECTROCHEMICAL (PEC) LIFTOFF TECHNIQUE,” attorney's docket number 30794.576-WO-U1 (2015-205-2); which application claims the benefit under 35 U.S.C. §119(e) of co-pending and commonly-assigned U.S. Provisional Application Ser. No. 62/069,644, filed on Oct. 28, 2014, by David Hwang, Nathan G. Young, Ben Yonkee, Burhan K. Saifaddin, Steven P. DenBaars, James S. Speck and Shuji Nakamura, entitled “FLEXIBLE ARRAYS OF MICRO-LEDS USING A PHOTOELECTROCHEMICAL (PEC) LIFTOFF TECHNIQUE,” attorney's docket number 30794.576-US-P1 (2015-205-1); both of which applications are incorporated by reference herein.

This application also claims the benefit under 35 U.S.C. §119(e) of co-pending and commonly-assigned U.S. Provisional Application Ser. No. 62/329,696, filed on Apr. 29, 2016, by David Hwang, Steven P. DenBaars, James S. Speck and Shuji Nakamura, entitled “SELF-EMISSIVE INORGANIC LED-BASED DISPLAY AND METHODS FOR PREPARING THE SAME,” attorney's docket number 30794.617-US-P1 (2016-604-1); which application is incorporated by reference herein.

### BACKGROUND OF THE INVENTION

1. Field of the Invention

This invention is related to the fabrication of III-V light-emitting diodes (LEDs), including arrays of III-nitride micro-LEDs, using a photoelectrochemical (PEC) etch or liftoff technique.

2. Description of the Related Art

(Note: This application references a number of different publications and patents as indicated throughout the specification by one or more reference numbers in brackets, e.g., [x]. A list of these different publications and patents ordered according to these reference numbers can be found below in the section entitled “References.” Each of these publications and patents is incorporated by reference herein.)

Commercially available display technologies include liquid crystal displays (LCDs) and organic light-emitting diode (OLED) based displays. However, the energy efficiency of these displays is limited, even by state of the art technologies.

LCDs are comprised of many components that are inefficient. The lighting mechanism in an LCD is a backlight unit, which is currently predominantly made of gallium nitride (GaN) based LEDs that give off white light. An alternative backlight would be made of a fluorescent lamp, which would be even more inefficient than an LED backlight unit. Beyond this backlighting unit, there are polarizers, liquid crystals, and color filters, which all block or lose some of the light emitted from the backlight unit. Altogether, the energy efficiency of an LCD can be less than 10%.

OLED based displays function using a different lighting mechanism, but are also limited in terms of energy efficiency. OLED based displays are self-emissive in that subpixels of red-green-blue (RGB) OLEDs form pixels, wherein the RGB subpixels are made of different colored OLEDs that either directly emit a red, green, or blue color or are covered with a filter to achieve the necessary color. State of the art OLEDs limit the energy efficiencies of OLED based displays to less than 30%.

Inorganic III-V compound semiconductors can be more energy efficient than their organic counterparts. The term “III-V compound semiconductor” refers to any alloy composition that uses a combination of B, Ga, Al, or In for the group III element and N, P, As, or Sb for the group V element. III-nitride LEDs such as GaN LEDs are one common type of IIIV devices.

Commercially available III-nitride LEDs typically have thin films that are epitaxially grown in the c-direction [0001] on sapphire substrates. However, III-nitride thin films grown on sapphire have high threading dislocation (TD) densities on the order of 10⁹-10¹⁰ cm⁻² [1], which degrade material quality and inhibit optical performance.

To overcome these problems, efforts have therefore been made to grow on bulk GaN substrates. These bulk substrates include numerous orientations, including the basal c-plane {0001}; nonpolar a-plane {1 1-2 0} and m-plane {1 0-1 0} families; and semipolar plane families such as the {1 0-1 1} and {2 0-2 1} planes, to name a few. However, such substrates are rigid substrates, which result in rigid devices, and there is an increasing demand for flexible electronic devices.

For example, there is an increasing demand for flexible displays. However, inorganic III-V compound semiconductor displays currently cannot be made flexible, do not have a high throughput fabrication method such as roll-by-roll printing used for OLED displays, and are limited in resolution and size. In order to address these issues, the pixels of a display need to be in the scale of tens of micrometers.

One reason that inorganic III-V compound semiconductor displays are not commercially viable is because no pick-and-place method can handle their small dimensions. Conventional pick-and-place methods utilize vacuum holes that have diameters of hundreds of micrometers. The smallest size of an inorganic III-V compound semiconductor device must be larger than the vacuum hole and must therefore must have dimensions on the scale of hundreds of micrometers.

Thus, there is a need for improved methods of fabricating III-nitride LEDs for use, for example, in display-related products, in order to reduce their power consumption. The present invention satisfies this need.

### SUMMARY OF THE INVENTION

To overcome the limitations in the prior art described above, and to overcome other limitations that will become apparent upon reading and understanding the present specification, the present invention discloses methods of fabricating III-V electronic or optoelectronic devices.

In one method, a III-nitride device structure, including an active layer between an n-type layer and a p-type layer, is fabricated on or above a polymer film by: (a) growing a sacrificial layer on or above a host substrate, wherein the sacrificial layer comprises a III-nitride layer; (b) growing the III-nitride device structure on or above the sacrificial layer, wherein the III-nitride device structure comprises a top surface and a bottom surface with the bottom surface adjacent the sacrificial layer; (c) preparing a submount with the polymer film deposited thereon; (d) flip-chip bonding the top surface of the III-nitride device structure onto the polymer film of the submount; (e) removing the sacrificial layer to separate the host substrate from the III-nitride device structure, wherein the sacrificial layer is removed using a photoelectrochemical (PEC) etch technique; and (f) delaminating the polymer film and the III-nitride device structure from the submount.

In another method, one or more III-V compound semiconductor micro light-emitting devices are fabricated by: (a) growing epitaxial films of III-V compound semiconductor material on a host substrate, wherein the epitaxial films include a sacrificial layer; (b) patterning the epitaxial films into micro devices on the host substrate and adding electrical contacts to the micro devices; (c) patterning structures in the epitaxial films that expose a sacrificial layer to be removed; (d) patterning anchoring structures that connect the micro devices to the host substrate; (e) removing the sacrificial layer via a photoelectrochemical (PEC) etch, wherein the sacrificial layer is immersed in a chemical solution and exposed to a light source; (f) separating the micro devices from the host substrate by bonding the micro devices to a temporary substrate and mechanically fracturing the anchoring structures that connect the micro devices to the host structure; and (g) transferring the separated micro devices from the temporary substrate onto a second substrate. A third substrate may be bonded to exposed surfaces of the transferred micro devices, thereby sandwiching the micro devices between the second and third substrates.

### BRIEF DESCRIPTION OF THE DRAWINGS

Referring now to the drawings in which like reference numbers represent corresponding parts throughout:

FIG. 1 is a flowchart illustrating a method of fabricating a device according to one or more embodiments of the invention.

FIG. 2 is a schematic of an example device structure, according to one or more embodiments of the invention, comprising a c-plane GaN substrate with 3 μm of n-type GaN (n-GaN), an InGaN/GaN sacrificial layer absorbing electromagnetic radiation having a wavelength of 415 nanometers (nm), 2.2 μm of n-GaN, an active region including an InGaN/GaN multi-quantum well absorbing electromagnetic radiation having a wavelength of 450 nm, and 150 nm of p-type GaN (p-GaN).

FIG. 3 is a schematic of an example of a processed device structure, according to one or more embodiments of the invention, comprising the layers in FIG. 2 and further including a p-type contact (p-contact), a dielectric, and a PEC contact.

FIG. 4 is a schematic illustrating an apparatus for PEC etching the device structure of FIG. 3 attached to a flexible polymer substrate on a submount, according to one or more embodiments of the invention.

FIG. 5 is a schematic of an example of a processed device structure that has been flip-chip bonded to a flexible polymer substrate on a submount, wherein the host substrate has been removed, according to one or more embodiments of the invention.

FIG. 6 is a schematic of a flexible array of micro-LEDs, including the example processed device structure of FIG. 5 comprising a plurality of RGB light-emitting III-nitride (or other) LEDs on top of a thin layer of metal on top of the flexible polymer substrate, according to one or more embodiments of the invention.

FIGS. 7(a)-7(j) are schematics that illustrate a fabrication method of the present invention.

FIGS. 8(a)-8(e) are schematics that illustrate an assembly method of the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

### Flexible Arrays of Micro-Leds Using a PEC Liftoff

### Overview

One or more embodiments of the present invention describe a method to fabricate a flexible, bendable and/or stretchable array of III-nitride micro devices, including but not limited to, light-emitting devices (e.g., VCSELs) and detectors, etc., by PEC liftoff

The method combines the epitaxy of III-nitride thin films for a device structure on a rigid host substrate, the flip-chip bonding of the device structure to a flexible film substrate deposited on a submount, and the use of a PEC etch technique to lift off the device structure and remove the rigid host substrate. The PEC etch technique is sensitive to dislocations and does not completely etch materials with TD densities greater than 10⁹ cm⁻². The term “flip-chip bonding” refers to wafer bonding the device structure and host substrate to a submount, so that the device structure is positioned between the submount and the host substrate.

### Fabrication Process

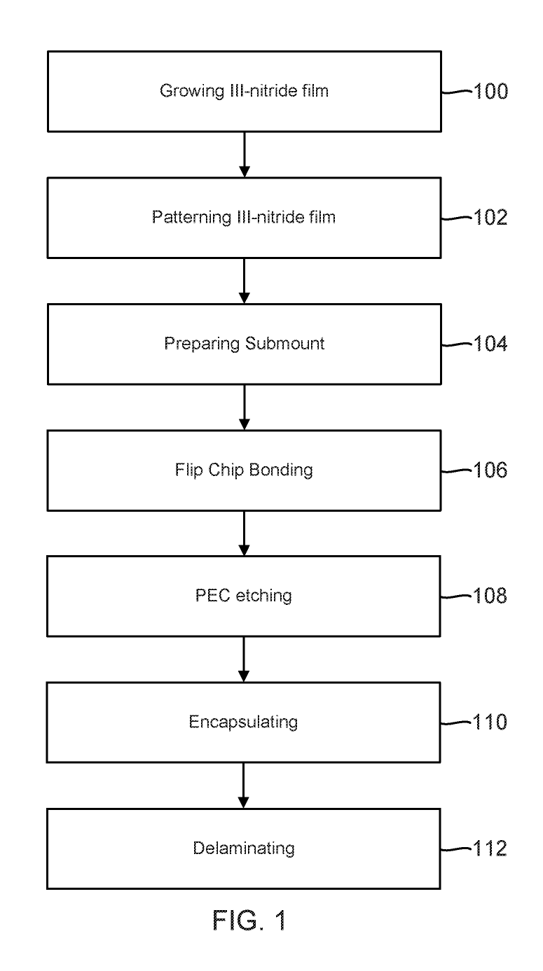

FIG. 1 illustrates a method involving the growing III-nitride films on bulk polar, nonpolar, or semipolar GaN substrates (Block 100), patterning the films into micro devices (Block 102), preparing or obtaining a submount with a suitable flexible substrate (Block 104), flip-chip bonding the micro devices to the suitable flexible substrate on the submount (Block 106), PEC etching a sacrificial layer to remove the micro devices from the rigid host substrate (Block 108), encapsulating the devices with a thin transparent film (Block 110), and delaminating the polymer film from the submount (Block 112), resulting in a flexible array of III-nitride devices (e.g., micro-LEDs). Previous attempts have been made to fabricate flexible GaN LEDs, but these attempts did not use a PEC etch technique to remove the substrate and did not use bulk GaN substrates [2-5].

PEC etching of III-nitrides on various substrates, such as silicon carbide [6,18], sapphire [7-12], and silicon [5], has been previously explored. PEC etching is a dopant-selective, bandgap-selective, and defect-selective etch method that can be used to perform top-down etching or undercut etching.

The PEC etch technique requires emission of light comprising photons having an energy that is larger than the bandgap of the material to be etched. The light generates charge carriers (electrons and holes), which are then separated by electric fields within the material.

The PEC etch technique described in one or more embodiments of the invention makes use of an n-i-n structure. Because of the ways the bands bend in the equilibrium diagram, holes are confined to the intrinsic layer. In the GaN material system, holes react with GaN in an oxidizing electrolyte solution, such as potassium hydroxide (KOH), to create gallium oxide (Ga₂O₃). This oxide can then be dissolved in KOH, wherein the dissociation of the oxide achieves the actual etching of GaN.

The technique is dopant-selective because it can etch n-type III-nitride semiconductor materials selectively over p-type [13]. The technique is bandgap-selective because it requires the light emitted from the light source to comprise photons having an energy larger than the bandgap of the material to be etched [14]. The technique is defect-selective because defects act as traps for the holes, which slows or prevents the etching of the material [8,15]. Therefore, this PEC etch technique will only work on materials that are not highly defective; highly defective in this case refers to TD densities of greater than 10⁹ cm⁻².

An example process flow using the method illustrated in FIG. 1 is further described below.

### Growth of Sacrificial Layer and Device Structure (e.g., Block 100)

Block 100 represents growing a sacrificial layer on a host substrate (e.g., bulk GaN), wherein the sacrificial layer comprises a III-nitride layer; and growing a III-nitride device structure on or above the sacrificial layer, wherein the III-nitride device structure comprises a top surface and a bottom surface, the bottom surface adjacent and interfacing the sacrificial layer, and opposite the top surface. The host substrate can have a threading dislocation density less than 10⁹ cm⁻². The III-nitride device structure can include an n-type layer/intrinsic layer/n-type layer (n-i-n) structure (i.e., intrinsic layer between n-type layers).

First, a thick layer of n-type GaN is grown (1-4 μm thick) on the host substrate. The sacrificial layer is then grown and can be comprised of (e.g., a six-period) InGaN/GaN multi quantum well (MQW), wherein the InGaN composition of the InGaN layer in the sacrificial layer is tuned such that the bandgap of the InGaN layer is smaller than the photon energy of the light emitted from the light source used for the PEC liftoff.

The layers above the sacrificial layer can comprise a micro-LED device structure. On or above the sacrificial layer is another thick layer of n-GaN that completes the n-i-n structure needed for the PEC etch, although any material with a wider bandgap (e.g., AlGaN) could be used.

After the n-GaN growth, the active region is grown, which can be another 6-period InGaN/GaN MQW that determines the color of light emission. Depending on the desired emission wavelength, the active region can be made of any III-nitride composition.

Finally, a thin layer of p-type III-nitride is grown. The III-nitride device structure including a p-type layer, n-type layer, and active region between the n-type layer and the p-type layer can have a thickness of 3 micrometers or less, for example.

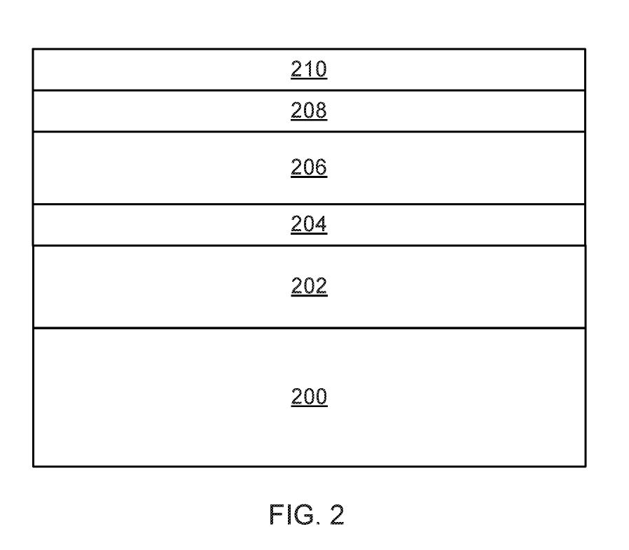

FIG. 2 is a schematic of an example device structure that can be grown, comprising a c-plane GaN substrate 200 (as the host substrate) with a 3 μm thick n-type GaN layer 202 deposited thereon, a sacrificial layer comprising an InGaN/GaN sacrificial layer (6 period MQW) 204 absorbing violet electromagnetic radiation (e.g., having a wavelength λ=415 nm), a 2.2 μm thick n-GaN layer 206, an active region 208 comprised of (e.g., a 6 period) InGaN/GaN MQW absorbing blue electromagnetic radiation at a wavelength λ=450 nm, and a 150 nm thick p-type GaN layer 210. The device structure may be grown by MOCVD or MBE, for example.

The choice of host substrate 200 on which to grow is crucial to the PEC etch. Many commercially available III-nitride LEDs use thin films that are grown on sapphire substrates. However, III-nitride thin films grown on sapphire have high TD densities on the order of 10⁹ cm⁻² [1], which degrade the material quality and could inhibit optical performance.

Efforts have therefore been made to grow on bulk GaN substrates, resulting in no mismatch. These bulk substrates include numerous orientations, including the basal c-plane {0001}; nonpolar a-plane {1 1-2 0} and m-plane {1 0-1 0} families; and semipolar plane families such as {1 0-1 1} and {2 0-2 1}, among others. The method described herein applies to all of these orientations.

### Patterning of Devices (e.g., Block 102)

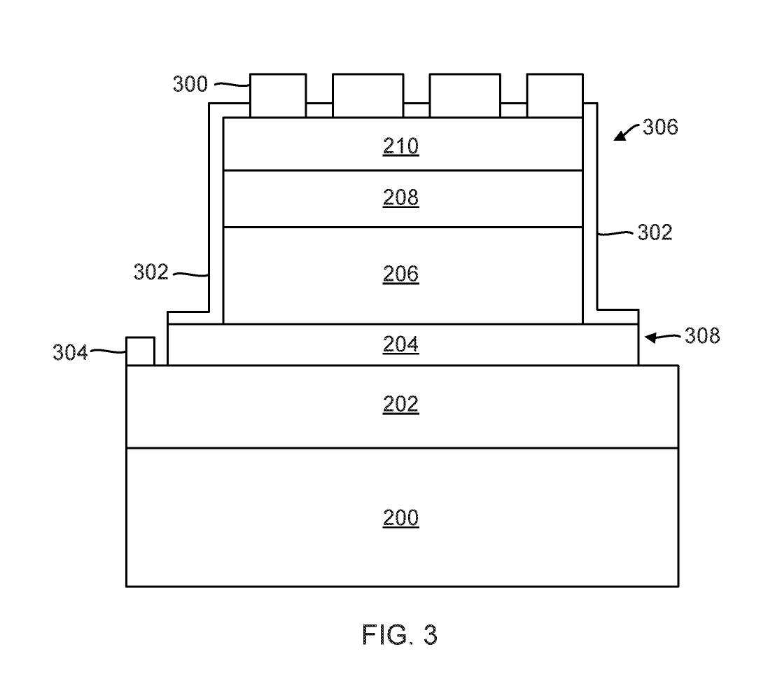

The thin films can then be patterned (e.g., into micro-LED devices), as represented in Block 102 of FIG. 1, and other materials (e.g., metals) are deposited to serve as or form n-type contacts (n-contacts) and p-type contacts (p-contacts). An example of the result of this processing is shown in FIG. 3, which is a schematic of an example processed device structure comprising the layers in FIG. 2 and further including a p-contact 300, a dielectric 302, and a PEC contact 304, a first mesa 306, and a second mesa 308 formed by the patterning.

The p-contact 300 is deposited onto the p-type III-nitride 210, the mesa 306 is formed so that the dielectric 302 (e.g., silicon nitride) protects the active region 208, the mesa 308 is formed to expose the sacrificial layer 204, and the PEC contact 304 is deposited to serve as the contact to the oxidizing electrolyte. Protection of the active region 208 during the PEC etch is provided by the dielectric layer 302.

After patterning, the devices can have a surface area less than 0.1 μm² and/or the device structure has a thickness of 3 micrometers or less.

Preparing a Submount with Polymer Film Deposited Thereon (e.g., Block 104)

A flexible substrate can then attached to the (e.g., micro-LEDs) via the p-contact 300 in a flip-chip bonding process. First, the submount must be prepared [16,17]. A thin film (e.g., ˜24 μm thick) of polyimide, or other suitable polymer, such as polyethylene terephthalate, is placed (spin-coated, rolled, etc.) onto a submount comprising a silicon wafer (although other wafers such as SiC or sapphire may be used), and the film is subsequently cured.

Then, a layer (50 nm-3 μm thick) of material similar to the p-contact 300 (e.g., metal such as gold, copper, etc.) is deposited onto the polymer film, in order to promote bonding to the p-contact 300 of the device structure. The material may be patterned to provide subsequent individual addressability to the bonded devices. The deposition of the polymer and the material similar to the p-contact 300 may also be repeated in order to provide a more adequate network of contacts to the attached devices.

### Flip-Chip Bonding the Top Surface of the III-Nitride Device Structure Onto the Polymer Film of the Submount (e.g., Block 106)

The resulting submount is then flip-chip bonded to the p-contact 300 of the device structure at a temperature between 200° C. and 400° C. for between 1-3 hours. After this step, the sacrificial layer (e.g., 204) is positioned in between the host substrate (e.g., 200) and submount, and is subsequently exposed.

### Removing the Sacrificial Layer to Separate the Host Substrate From the Device Structure, Wherein the Sacrificial Layer is Removed Using a PEC Etch Technique (e.g., Block 108)

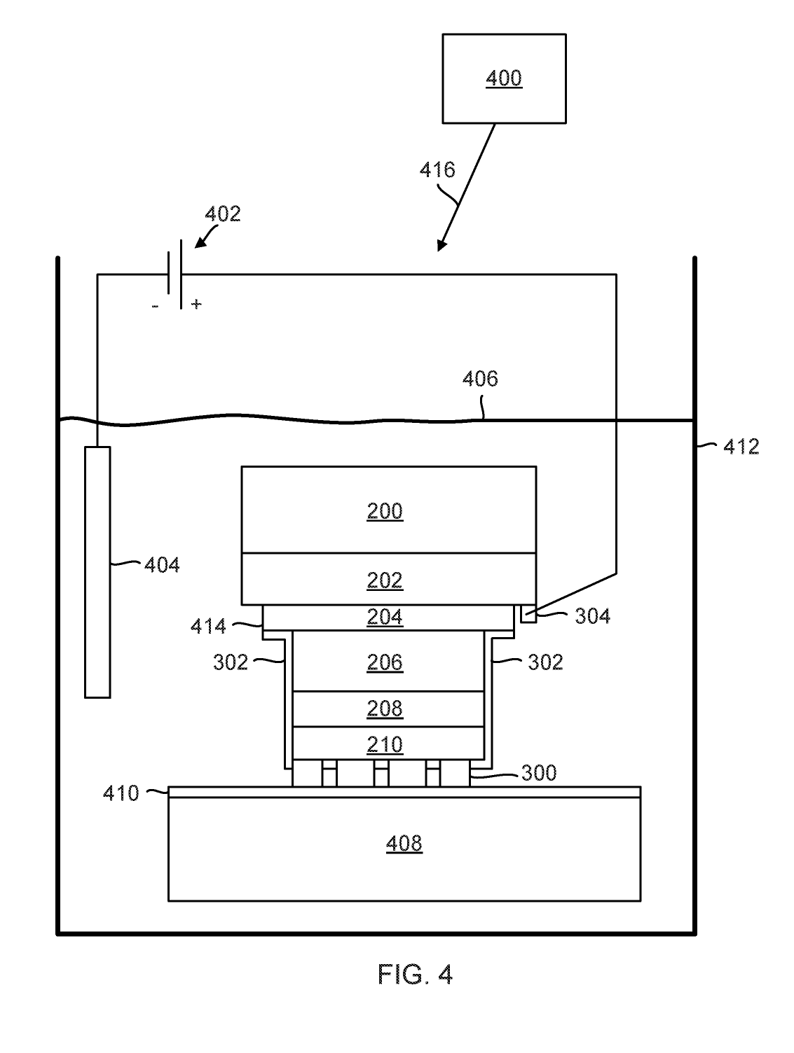

The removal of the host substrate is done via a PEC etch. The PEC etch setup is comprised of a light/electromagnetic radiation source 400 and an electrochemical cell (comprising voltage source 402, cathode 304, and electrode 404) with an oxidizing electrolyte 406, such as KOH, as illustrated in FIG. 4. Specifically, the structure of FIG. 3 attached to a submount 408 and polymer film 410 is immersed in a solution of KOH 406 that has a molarity between 0.001 and 1, wherein the solution 406 is in a container 412. The cathode 304 is a metal deposited on the semiconductor, which is labeled as the PEC contact 304 in FIG. 3, and the anode is the semiconductor surface 414. The solution 406 may be constantly stirred, for example, by a magnetic stirrer.

The sacrificial layer 204 is an intrinsic region as described above, so holes are confined to the sacrificial layer 204 and will etch the sacrificial layer 204. The light source 400 emitting light/electromagnetic radiation 416 with an approximate wavelength of 400 nm, corresponding to a photon energy which is larger than the bandgap of the sacrificial layer 204, shines onto the structure until the sacrificial layer 204 is completely etched. Specifically, the PEC etch technique exposes the sacrificial layer 204 to the solution 406 (e.g., comprising KOH and water) and applies light 416 from a light source 400 causing the sacrificial layer 204 to etch in the solution 406. This undercut etch completes the removal of the host substrate 200 and n-GaN 202 from the layers 206, 208, 210.

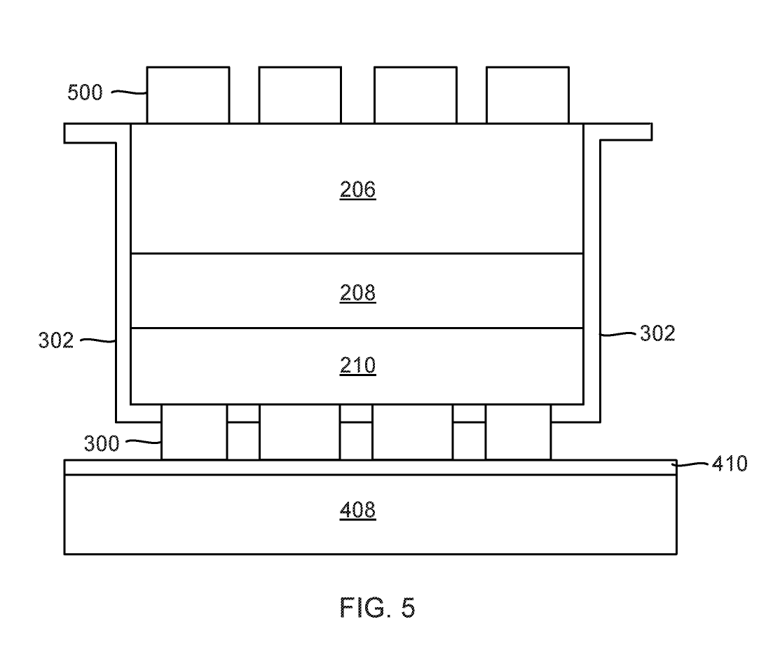

To complete the fabrication of the micro-LED devices, the device structure 206, 208, 210 is patterned for n-contact deposition and an n-type contact (n-contact) 500 is deposited on the n-GaN 206, as illustrated in FIG. 5. FIG. 5 is a schematic of the processed device structure 206, 208, 210, 300, 302, 500 that has been flip-chip bonded to the polymer film 410 and submount 408, wherein the host substrate 200 has been removed.

Finally, a flexible and transparent thin film (not shown) may be blanket deposited to encapsulate and protect the device structure (Block 110).

### Delaminating the Polymer Film From the Submount (e.g., Block 112)

Finally, the polymer film 410 is delaminated from the submount/wafer 408 (e.g., silicon wafer), for example, using a razor blade or other means to cut the polymer film 410 around the devices, as represented by Block 112 of FIG. 1.

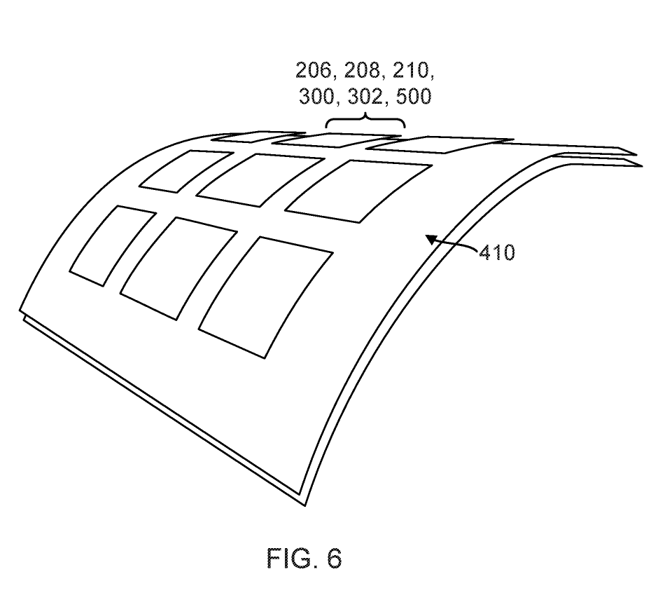

In one or more embodiments, the resulting product is a flexible array of III-nitride micro-LEDs (e.g., RGB LEDs) on the polymer film 410, as shown in FIG. 6, which is a schematic of a flexible array of III-nitride micro-LEDs, each having the structure shown in FIG. 5, i.e., comprised of 206, 208, 210, 300, 302, 500, on top of the polymer film 410 (the encapsulating layer is not shown). The RGB LEDs can comprise at least one LED emitting at a peak wavelength corresponding to red (R) light, at least one LED emitting at a peak wavelength corresponding to green (G) light, and at least one LED emitting at a peak wavelength corresponding to blue (B) light.

However, other devices can also be fabricated. One or more embodiments of the invention describe a method of fabricating a flexible array of III-nitride (e.g., micro devices), including but not limited to light-emitting devices (e.g., vertical-cavity surface-emitting lasers (VCSELs)) and detectors. For example, the device can comprise a transistor, a light emitting diode, a laser diode, a solar cell, or an array of devices such as an array of micro-LEDs, lasers, solar cells, or transistors, grown from a III-nitride (e.g., GaN) substrate and formed on a flexible substrate.

Thus, FIGS. 1-6 illustrate an optoelectronic or electronic device (e.g., a transistor, a light emitting diode, a laser, or a solar cell), comprising a flexible polymer substrate; a III-nitride device structure on the flexible polymer substrate, the III-nitride device including an active layer between an n-type layer and a p-type layer, the optoelectronic or electronic device fabricated using a process comprising (a) growing a sacrificial layer on a host substrate, wherein the sacrificial layer comprises a III-nitride layer; (b) growing the III-nitride device structure on or above the sacrificial layer, wherein the III-nitride device structure comprises a top surface and a bottom surface, the bottom surface interfacing the sacrificial layer and opposite the top surface; (c) preparing a submount with a polymer film deposited thereon; (d) flip-chip bonding the top surface of the III-nitride device structure onto the polymer film of the submount; (e) removing the sacrificial layer to separate the host substrate from the device structure, wherein the sacrificial layer is removed using a photoelectrochemical (PEC) etch technique; and (f) delaminating the polymer film from the submount. The device can comprise an array of micro-LEDs grown from a GaN substrate and formed on a flexible substrate, for example.

### Possible Modifications and Variations

One or more embodiments of the invention describe how III-nitride micro devices grown on bulk GaN substrates can be flip-chip bonded to a flexible substrate on a submount and then lifted off from the rigid host substrate by a PEC etch. By choosing an appropriate flexible substrate, and by properly handling of the submount, a method according to one or more embodiments of the present invention can be used to fabricate a flexible array of III-nitride micro devices. One difficulty is that flip-chip wafer bonding to a flexible substrate is nearly impossible since there is no rigidity. By preparing a flexible film on a rigid substrate and then removing that flexible film, the difficulty in bonding can be overcome.

In this context, “micro devices” refers to devices with areas that may be less than 0.1 μm² and that may have side lengths of approximately 300 μm or less. However, the invention described herein may be applied to devices with larger areas and side lengths. The geometries of the devices may include rectangular, circular, or triangular shapes, although other device geometries not described here may also be used.

The method described herein applies to any of the orientations used with III-nitride devices. Specifically, the method of the present invention can be used with III-nitride thin films that are epitaxially grown in the c-direction [0001] on sapphire substrates or on various orientations used with bulk GaN substrates, such as the basal c-plane {0001}; nonpolar a-plane {1 1-2 0} and m-plane {1 0-1 0} families; and semipolar plane families such as {1 0-1 1} and {2 0-2 1}. However, other device materials compatible with PEC etching could also be used.

### Advantages and Improvements

One or more embodiments of the present invention are commercially advantageous because they allow for the development of flexible arrays of III-nitride micro devices. Specifically, a flexible array of III-nitride (inorganic) LEDs can be created. The flexible

LED area is one that has been previously dominated by OLEDs. Thus, one or more embodiments of the invention have many applications that include, but are not limited to, flexible displays for mobile phones and wearable electronics with curved surfaces and displays.

The use of the PEC liftoff technique will also allow for substrate recycling. Bulk GaN substrates are expensive, so the ability to reuse a bulk GaN substrate will be economical.

### Self-Emissive Inorganic Led-Based Displays and Methods for Preparing the Same

### Overview

This invention describes display pixels fabricated from inorganic III-V compound semiconductor micro devices, such as LEDs or VCSELs. III-V compound semiconductors are inorganic and can be used to create self-emissive micro-LEDs that serve as RGB subpixels in a display.

The fabrication method described herein comprises the steps of: growing epitaxial films of III-V compound semiconductor material on a host substrate (e.g., silicon, sapphire, GaN, GaAs); forming patterns and mesas that comprise the micro devices; affixing select areas of the devices onto the substrate through patterning of the epitaxial material or through addition of other materials (such as metal, dielectrics, or polymers); undercutting the devices with a PEC etch, so as to partially separate the devices from the substrate; transfer printing by attaching an intermediate substrate as a transfer medium to the surfaces of the devices;

mechanically fracturing the material affixing the device to the host substrate; bonding the separated device to a second substrate of any material; and removing the transfer medium, so that the micro device effectively has been transferred from the host substrate onto the second substrate. The result of these steps is that micro devices on the scale of tens of micrometers may be fabricated and handled.

### Fabrication Process

The present invention describes methods to fabricate display pixels using inorganic III-V compound semiconductor light-emitting micro devices, such as micro LEDs or VCSELs. One novel aspect of the present invention is to combine PEC etching and thin film layer transfer via a rubber stamp or other elastomer. With these methods, RGB subpixels can be arranged side-by-side to form pixels that have lateral dimensions smaller than 60 μm.

The fabrication method of the present invention includes the following steps: (1) growth of a sacrificial layer and III-V compound semiconductor light-emitting films on a host substrate; (2) patterning the films into micro devices and patterning structures to allow for the devices to be released from the substrate; (3) partial release of the micro devices from the substrate; (4) transfer of the devices onto an intermediate substrate as a transfer medium and then onto another second substrate; and (5) attaching a final third substrate to the top of the devices so that the devices are sandwiched between the second and third substrates.

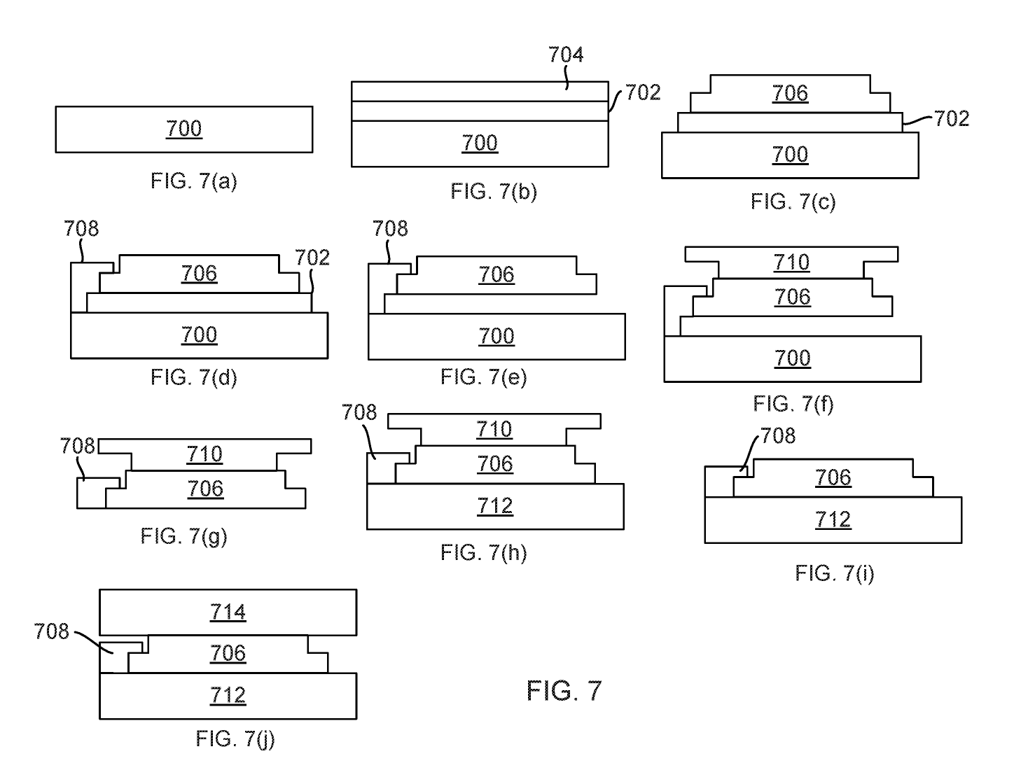

First, the method to transfer subpixels of one color will be described. These steps are illustrated by the schematics in FIGS. 7(a)-7(j).

In the growth step (1), a host substrate 700 is provided, as shown in FIG. 7(a), and a sacrificial layer 702 and III-V epitaxial film 704 comprising light-emitting layers are grown on or above the substrate 700, as shown in FIG. 7(b), wherein the sacrificial layer 702 is positioned underneath the subsequently-grown III-V epitaxial film 704.

In one embodiment, the device would be an LED from the III-N family and the III-V epitaxial film 704 includes at least p-type GaN, an active layer made of InGaN/GaN multi-quantum wells, n-type GaN, and the sacrificial layer 702 includes at least InGaN/GaN quantum wells. In another embodiment, the device would be an AlInGaP LED, and the sacrificial layer may be an AlAs layer.

The growth can either be done homoepitaxially, where the substrate 700 is the same material as that of the LED, or heteroepitaxially, where the substrate 700 is a foreign material from that of the LED, such as sapphire, silicon, silicon carbide, etc.

In the patterning step (2), micro devices 706 are patterned in the film 704, so that the devices 706 are the appropriate size, the sacrificial layer 702 is exposed, the light-emitting layer is protected, and anchors 708 are added, as shown in FIGS. 7(c) and 7(d).

Mesas are first created to expose the sacrificial layer 702 for PEC etching. Any other layers that may be affected by the PEC etching are protected by depositing dielectric material around them so that they are isolated from electrolyte. Any metallization to electrically contact the n- and p-doped semiconductor is performed. Transparent conducting oxides (TCOs) may also be used to electrically contact the semiconductor, wherein these transparent contacts lead to transparent pixels and transparent displays. The final lateral dimensions of the devices 706 may be smaller than 50 μm.

The anchors 708 physically keep the devices 706 attached to the substrate 700, so that the devices 706 do not float freely in solution during the PEC etch.

In the release step (3), the micro devices 706 are released by way of a sacrificial etch, as shown in FIG. 7(e). In one embodiment, the devices 706 would be InGaN LEDs with a sacrificial layer 702 that comprises InGaN/GaN quantum wells.

The sacrificial etch is a PEC etch, wherein the structure is immersed into an electrolyte and light is shined onto the structure. The light source may be an LED array emitting light with a wavelength of around 405 nm and the electrolyte would be KOH. The light generates electron-hole pairs within the sacrificial layer 702, which has a band gap smaller than a photon energy of the light. Photogenerated carriers react chemically to etch away the sacrificial layer 702.

Depending on the band gap of the active layer multi-quantum wells, holes and electrons may also be photogenerated within the active layer. However, if the active layer is protected with dielectric, it will not be etched.

After the etch, the devices 706 are partially released, but are still attached to the substrate 700 through the anchor 708, as shown in FIG. 7(e).

In another embodiment, where the devices 706 are AlInGaP LEDs, the sacrificial layer 702 could be AlAs. The release mechanism would then be a selective etch using various acids and/or bases.

In the transfer step (4), an intermediate temporary substrate, such as a rubber stamp or other elastomer, is temporarily bonded to the top of the devices 706 as a transfer medium 710, as shown in FIG. 7(f). A rubber stamp can be prepared so that it has some certain tackiness, such that it will stick to the devices 706 easily. At this point, the devices 706 are between the substrate 700 (below) and the transfer medium 710 (above), forming one group.

Once attached to the transfer medium 710, the devices 706 are then permanently removed from the first host substrate 700 by mechanical fracture of the anchor 708 that held the devices 706 to the substrate 700, as shown in FIG. 7(g). The mechanical fracture is done by physically ripping the transfer medium 710 away from the host substrate 700 below the devices 706. The anchors 708 are thin enough that the mechanical fracture requires little force. At this point, the tops of the devices 706 are now temporarily bonded to the transfer medium 710.

The devices 706 are then transferred to another second substrate 712 and released from the transfer medium 710, so that the bottom of the devices 706 are bonded to the top of the second substrate 712, as shown in FIGS. 7(h) and 7(i). Once the devices 706 are bonded to the second substrate 712, any final encapsulation or interconnect metallization that is necessary is performed.

The second substrate 712 can be made of any material. For heat sinking purposes, silicon carbide would be advantageous. For optical transparency purposes, glass or sapphire may be desired. For flexibility purposes, a polymeric film such as polyimide or polyethylene terephthalate would be used.

In the attaching step (5), a final third substrate 714 may be attached to the top surface of the devices 706, as shown in FIG. 7(j). Prior to attaching the third substrate 714 to the devices 706, the third substrate 714 may be patterned with electrical interconnections, which may be comprised of metal or a TCO to allow for transparency. When the third substrate 714 is eventually attached, the devices 706 are then able to be electrically contacted through these patterns on the substrate 714.

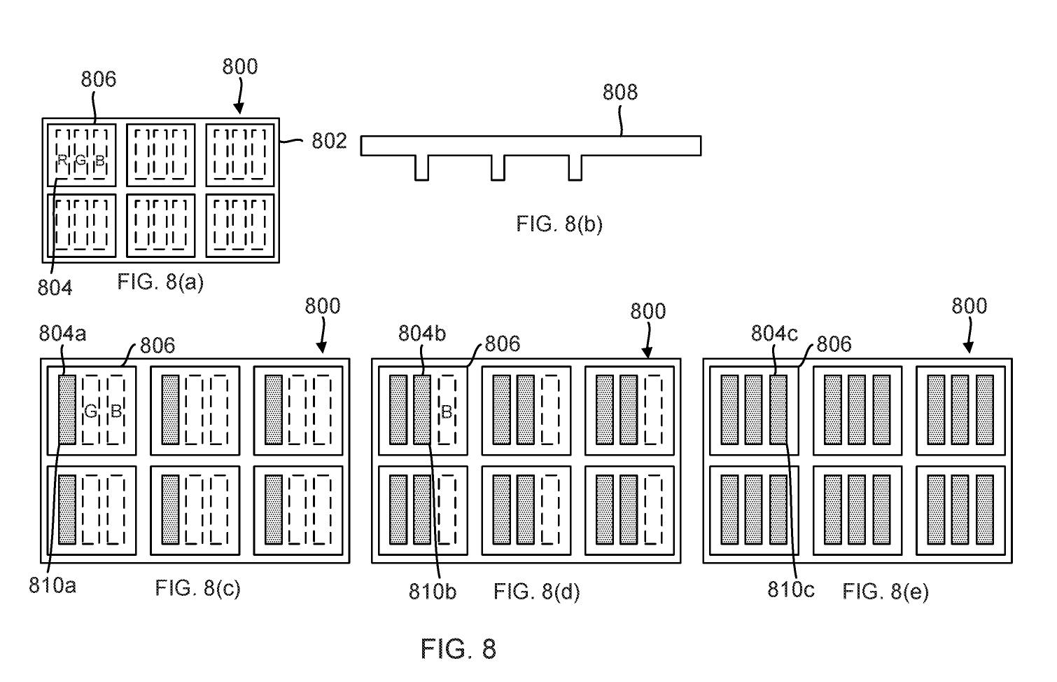

The technique to assemble and arrange RGB subpixels is shown in FIGS. 8(a)-8(e), followed by various applications that are made possible with this invention. Specifically, FIGS. 8(a)-(e) illustrate a method to assemble and arrange RGB subpixels side-by-side on the second substrate to create pixels of a display. The technique is similar to the technique for transferring one subpixel described in FIGS. 7(a)-7(j).

In order to create a full-color display, three sources of epitaxially grown material are needed: one for red, one for green, and one for blue. These epitaxial films can be made of different compositions (such as III-nitrides, III-arsenides, etc.). Subpixels of one color will be transferred onto a final substrate while leaving space for the subpixels of the two other colors.

One example pattern 800 is shown in a top-down perspective in FIG. 8(a), but any pattern can used. The larger outer rectangle 802 represents an area of a display. The long dashed rectangles 804 indicate empty spaces where light-emitting devices should be placed, wherein each dashed rectangle 804 comprises a subpixel (they are marked R, G, or B to represent the color of the subpixel). The squares 806 that encompass each three RGB subpixels represent an individual pixel, which in this embodiment are 25 μm on a side. In this example, the area of the display 802 includes two (2) rows, each row having three (3) pixels 806, and each pixel 806 having three (3) subpixels 804, labeled as red (R), green (G) or blue (B) subpixels 804.

The intermediate substrate or transfer medium 808 (e.g., the rubber stamp) upon which the light-emitting devices will be temporarily bonded can be molded and patterned so that it leaves enough spacing (e.g., 25 μm) between protrusions for bonding multiple (e.g., three) subpixels 804 of the same color into different pixels 806, as shown in FIG. 8(b).

To assemble the subpixels 804 and pixels 806, three light-emitting devices 810 of the same color are bonded to the three protrusions of the transfer medium 808 and subsequently placed into three of the same subpixel 804 spaces of the three pixels 806 in each row. The transfer is repeated, until all subpixel spaces 804 of the three pixels 806 in both rows are filled.

As shown in FIG. 8(c), three red light-emitting devices 810a are transferred into the three R subpixel 804a spaces of the three pixels 806 in both rows; as shown in FIG. 8(d), three green light-emitting devices 810b are transferred into the three G subpixel 804b spaces of the three pixels 806 in both rows; and as shown in FIG. 8(e), three blue light-emitting devices 810c are transferred into the B subpixel 804c spaces of the three pixels 806 in both row. At this point, all of the subpixels 804 and pixels 806 within the area of a display 802 are fully assembled.

### Modifications and Alternatives

The present invention provides a number of modifications and alternatives.

This invention allows for displays that can be integrated onto any surface by choosing an appropriate substrate.

In certain embodiments, the display will be flexible if the substrate chosen has the property of being flexible. Such substrates include polymeric materials, polyimide or polyethylene terephthalate. This substrate can then be attached to a curved surface such as a car windshield.

In certain embodiments, the display will be transparent if the substrate chosen and the metal contacts are transparent. These substrates and contacts could be glass and transparent conducting oxides, respectively.

In certain embodiments, the display will be opaque if the substrate is chosen as such. This embodiment will allow for high brightness displays by including a mirror that is made out of reflective material, such as silver.

### Advantages and Benefits

The present invention provides a number of advantages and benefits.

With state of the art III-V compound semiconductor LEDs, energy efficiencies can at least double that of OLED displays. Moreover, with the small pixel sizes of III-V compound semiconductor LEDs, ultra-high resolution can be achieved.

The combination of PEC etching and transfer printing allows for high throughput and yield during manufacturing. The combination of an undercut mechanism, such as PEC etching, and thin film layer transfer, through transfer printing, allows for unique display forms to be made.

Indeed, by using transfer printing, any size display can be fabricated with ultra-high resolution. In addition to display monitors or mobile phone displays, micro-LED displays can be used on near-eye and head-mountable technologies.

With this invention, displays that are flexible are possible as well. In addition to having curved television screens or mobile devices, these micro-LED displays can be integrated onto transparent surfaces, such as a car dashboard or a glass window. Therefore, this invention has many applications.

Transparent stand-alone displays are also possible with this invention. By using TCOs, such as indium tin oxide or zinc oxide, for metal contacts and transparent substrates, such as glass or a polymeric film, the entire device will be transparent.

### REFERENCES

The following publications, referenced above and incorporated by reference herein, are relevant to this disclosure:

[1] D. F. Feezell, M. C. Schmidt, S. P. DenBaars, and S. Nakamura, “Development of Nonpolar and Semipolar InGaN/GaN Visible Light-Emitting Diodes,” MRS Bull., vol. 34, no. 5, pp. 318-323, 2009.

[2] J. A. Rogers, “Microscale Inorganic Light-Emitting Diodes on Flexible and Stretchable Substrates,” IEEE Photonics J., vol. 4, no. 2, pp. 607-612, April 2012.

[3] D. -H. Kim, N. Lu, R. Ghaffari, and J. A. Rogers, “Inorganic semiconductor nanomaterials for flexible and stretchable bio-integrated electronics,” NPG Asia Mater., vol. 4, no. 4, p. e15, April 2012.

[4] S. -I. Park, Y. Xiong, R. Kim, P. Elvikis, M. Meitl, D. Kim, J. Wu, J. Yoon, C. Yu, Z. Liu, Y. Huang, K. Hwang, P. Ferreira, X. Li, K. Choquette, and J. A. Rogers, “Printed Assemblies of Inorganic Light-Emitting Diodes for Deformable and Semitransparent Displays,” Science, vol. 325, no. 5943, pp. 977-981,21 August 2009.

[5] H. G. Yoo, K. -I. Park, M. Koo, S. Kim, S. Y. Lee, S. H. Lee, and K. J. Lee, “Flexible GaN LED on a Polyimide Substrate for Display Applications,” in Quantum Sensing and Nanophotonic Devices IX, 2012, vol. 8268, p. 82681Y-82681Y-6.

[6] C. Youtsey, I. Adesida, L. T. Romano, and G. Bulman, “Smooth n-type GaN surfaces by photoenhanced wet etching,” Appl. Phys. Lett., vol. 72, no. 5, pp. 560-562, 1998.

[7] A. Tauzin, T. Akatsu, M. Rabarot, J. Dechamp, M. Zussy, H. Moriceau, J. F. Michaud, A. M. Charvet, L. Di Cioccio, F. Fournel, J. Garrione, B. Faure, F. Letertre, and N.

Kernevez, “Transfers of 2-inch GaN films onto sapphire substrates using Smart Cut technology,” Electron. Lett., vol. 41, no. 11, pp. 11-12, 2005.

[8] Y. Gao, M. D. Craven, J. S. Speck, S. P. Den Baars, and E. L. Hu, “Dislocation- and crystallographic-dependent photoelectrochemical wet etching of gallium nitride,” Appl. Phys. Lett., vol. 84, no. 17, p. 3322, 2004.

[9] M. S. Minsky, M. White, and E. L. Hu, “Room-temperature photoenhanced wet etching of GaN,” Appl. Phys. Lett., vol. 68, no. 11, pp. 1531-1533, 1996.

[10] E. Trichas, C. Xenogianni, M. Kayambaki, P. Tsotsis, E. Iliopoulos, N. T. Pelekanos, and P. G. Savvidis, “Selective photochemical etching of GaN films and laser lift-off for microcavity fabrication,” Phys. Status Solidi, vol. 205, no. 11, pp. 2509-2512, November 2008.

[11] A. R. Stonas, T. Margalith, S. P. DenBaars, L. A. Coldren, and E. L. Hu, “Development of selective lateral photoelectrochemical etching of InGaN/GaN for lift-off applications,” Appl. Phys. Lett., vol. 78, no. 13, p. 1945, 2001.

[12] A. R. Stonas, P. Kozodoy, H. Marchand, P. Fini, S. P. DenBaars, U. K. Mishra, and E. L. Hu, “Backside-illuminated photoelectrochemical etching for the fabrication of deeply undercut GaN structures,” Appl. Phys. Lett., vol. 77, no. 16, pp. 2610-2612, 2000.

[13] R. Khare and E. L. Hu, “Dopant Selective Photoelectrochemical Etching of GaAs Homostructures,” J. Electrochem. Soc., vol. 138, no. 5, pp. 1516-1519, 1991.

[14] R. Khare, D. B. Young, and E. L. Hu, “The Bandgap-Selective Photoelectrochemical Etching of GaAs/AlxGal-xAs Heterostructures with Varying Mole Fraction,” J. Electrochem. Soc., vol. 140, no. 7, p. L117, 1993.

[15] B. Yang and P. Fay, “Etch rate and surface morphology control in photoelectrochemical etching of GaN,” J. Vac. Sci. Technol. B Microelectron. Nanom. Struct., vol. 22, no. 4, p. 1750, 2004.

[16] K. Takei, T. Takahashi, J. C. Ho, H. Ko, A. G. Gillies, P. W. Leu, R. S. Fearing, and A. Javey, “Nanowire active-matrix circuitry for low-voltage macroscale artificial skin.,” Nat. Mater., vol. 9, no. 10, pp. 821-6, October 2010.

[17] C. Wang, D. Hwang, Z. Yu, K. Takei, J. Park, T. Chen, B. Ma, and A. Javey, “User-interactive electronic skin for instantaneous pressure visualization,” Nat Mater, vol. 12, no. 10, pp. 899-904, 2013.

[18] U.S. Pat. No. 7,825,006, issued Nov. 2, 2010, to Shuji Nakamura and Steven DenBaars, entitled “Lift-off process for GaN films formed on SiC substrates and devices fabricated using the method.”

U.S. Patent Application Publication No. 2015/0372187 A1, published on Dec. 24, 2015, by Bower et al., entitled “Systems and methods for preparing GaN and related materials for micro assembly.”

[20] M. A. Meitl, Z. -T. Zhu, V. Kumar, K. J. Lee, X. Feng, Y. Y. Huang, I. Adesida, R. G. Nuzzo, and J. A. Rogers, “Transfer printing by kinetic control of adhesion to an elastomeric stamp,” Nat. Mater., vol. 5, no. 1, pp. 33-38, 2006.

[21] S. -I. Park, Y. Xiong, R. -H. Kim, P. Elvikis, M. A. Meitl, D. Kim, J. Wu, J. Yoon, C. Yu, Z. Liu, Y. Y. Huang, K. Hwang, P. Ferreira, X. Li, K. Choquette, and J. A. Rogers, “Printed assemblies of inorganic light-emitting diodes for deformable and semitransparent displays,” Science, vol. 325, no. 5943, pp. 977-981, 2009.

[22] H. Kim, E. Brueckner, J. Song, Y. Li, S. Kim, C. Lu, J. Sulkin, K. Choquette, Y. Huang, R. G. Nuzzo, and J. A Rogers, “Unusual strategies for using indium gallium nitride grown on silicon (111) for solid-state lighting,” Proc. Natl. Acad. Sci. U. S. A., vol. 108, no. 25, pp. 10072-10077, 2011.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating an optoelectronic or electronic device, comprising:
(a) growing a sacrificial layer on or above a host substrate, wherein the sacrificial layer comprises a III-nitride layer;
(b) growing a III-nitride device structure on or above the sacrificial layer, wherein the III-nitride device structure comprises a top surface and a bottom surface with the bottom surface adjacent the sacrificial layer;
(c) preparing a submount with a polymer film deposited thereon;
(d) flip-chip bonding the top surface of the III-nitride device structure onto the polymer film of the submount;
(e) removing the sacrificial layer to separate the host substrate from the III-nitride device structure, wherein the sacrificial layer is removed using a photoelectrochemical (PEC) etch technique; and
(f) delaminating the polymer film and the III-nitride device structure from the submount.

2. The method of claim 1, wherein the host substrate is a bulk gallium nitride (GaN) substrate having a polar, nonpolar or semipolar plane orientation.

3. The method of claim 1, wherein the submount is silicon, silicon carbide or sapphire.

4. The method of claim 1, wherein the polymer film is polyimide or polyethylene terephthalate.

5. The method of claim 1, wherein:
the sacrificial layer is comprised of an InGaN/GaN multi quantum well (MQW); and
the InGaN in the sacrificial layer has a bandgap smaller than a photon energy of light used in the PEC etch technique.

6. The method of claim 1, wherein the preparing further comprises:
depositing the polymer film onto the submount; and
depositing metal onto the polymer film, wherein the metal promotes bonding to a p-contact of the III-nitride device structure.

7. The method of claim 1, further comprising patterning the III-nitride device structure into micro devices prior to the flip chip bonding.

8. An optoelectronic or electronic device, comprising:
a III-nitride device structure on or above a polymer film, the III-nitride device structure including an active layer between an n-type layer and a p-type layer, the III-nitride device structure fabricated using a process comprising:
(a) growing a sacrificial layer on a host substrate, wherein the sacrificial layer comprises a III-nitride layer;
(b) growing the III-nitride device structure on or above the sacrificial layer, wherein the III-nitride device structure comprises a top surface and a bottom surface with the bottom surface adjacent the sacrificial layer;
(c) preparing a submount with the polymer film deposited thereon;
(d) flip-chip bonding the top surface of the III-nitride device structure onto the polymer film of the submount;
(e) removing the sacrificial layer to separate the host substrate from the III-nitride device structure, wherein the sacrificial layer is removed using a photoelectrochemical (PEC) etch technique; and
(f) delaminating the polymer film and the III-nitride device structure from the submount.

9. A method of fabricating one or more III-V compound semiconductor micro light-emitting devices, comprising:
(a) growing epitaxial films of III-V compound semiconductor material on a host substrate, wherein the epitaxial films include a sacrificial layer;
(b) patterning the epitaxial films into micro devices on the host substrate and adding electrical contacts to the micro devices;
(c) patterning structures in the epitaxial films that expose a sacrificial layer to be removed;
(d) patterning anchoring structures that connect the micro devices to the host substrate;
(e) removing the sacrificial layer via a photoelectrochemical (PEC) etch;
(f) separating the micro devices from the host substrate by bonding the micro devices to a temporary substrate and then mechanically fracturing the anchoring structures that connect the micro devices to the host structure; and
(g) transferring the separated micro devices from the temporary substrate onto a second substrate.

10. The method of claim 9, wherein the anchoring structures are patterned by depositing material onto the micro devices.

11. The method of claim 9, wherein the anchoring structures are patterned from the epitaxial films.

12. The method of claim 9, wherein the temporary substrate is a rubber stamp or other elastomeric material.

13. The method of claim 9, wherein the second substrate has electrical interconnections patterned thereon, and the electrical interconnections are made of metal or a transparent conducting oxide.

14. The method of claim 9, wherein the second substrate is a transparent substrate.

15. The method of claim 9, further comprising:
bonding a third substrate to exposed surfaces of the transferred micro devices, thereby sandwiching the micro devices between the second and third substrates.

16. The method of claim 15, wherein the third substrate has electrical interconnections patterned thereon, and the electrical interconnections are made of metal or a transparent conducting oxide.

17. The method of claim 15, wherein the third substrate is a transparent substrate.

18. The method of claim 9, wherein the transferring step comprises assembling subpixels into pixels on the second substrate using the transferred micro devices.

19. The method of claim 18, wherein the subpixels are red, green, and blue (RGB) subpixels.

20. The method of claim 19, wherein the red, green, and blue subpixels comprise different epitaxial films.
